(19) United States
(12) Patent Application Publication
(10) Pub. No.: US 2008/0093666 A1
(43) Pub. Date: Apr. 24, 2008

(54) Semiconductor Device and Manufacturing Method Thereof

(76) Inventor: Yasunori OKAYAMA, Kamakura-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/873,629

(22) Filed: Oct. 17, 2007

(30) Foreign Application Priority Data
Oct. 20, 2006 (JP) 2006-286915

(51) Int. Cl. H01L 27/092; H01L 21/8238

(52) U.S. Cl. 257/338; 438/231; 257/E27.062; 257/E21.632

(57) ABSTRACT

A semiconductor device having a simple structure with selectively formed full-silicide (FUSI) and partial silicide gate electrodes and a manufacturing method thereof are provided. According to one aspect, there is provided a semiconductor device includes a first field effect transistor (MOSFET), and a second MOSFET, the first MOSFET including a first gate electrode provided on a gate insulator on a semiconductor substrate and formed of a first metal silicide layer, a first insulator provided to be adjacent to the first gate electrode, and a first sidewall including the first insulator, the second MOSFET including a second gate electrode provided on a gate insulator on the semiconductor substrate and formed of a conductor film including a polysilicon layer and a second metal silicide layer, a second insulator provided to be adjacent to the second gate electrode, and a second sidewall including the second insulator.

### CROSS-REFERENCE TO RELATED APPLICATIONS

This application is based upon and claims the benefit of priority from prior Japanese Patent Application No. 2006-286915, filed Oct. 20, 2006, the entire contents of which are incorporated herein by reference.

### BACKGROUND OF THE INVENTION

1. Field of the Invention

The present invention relates to a semiconductor device including field effect transistors and a manufacturing method thereof, and more particularly to a semiconductor device using a metal silicide for a gate electrode and a manufacturing method thereof.

2. Description of the Related Art

When miniaturization of a field effect transistor (FET) advances, achieving both an improvement in transistor performance and suppression of variation in their characteristics is becoming difficult. In a complementary metal-oxide-silicon (CMOS) semiconductor device including n-channel MOSFETs (nMOSFETs) and p-channel MOSFETs (pMOSFETs), optimizing the nMOSFET and pMOSFET while considering their performance and variations in characteristics is demanded. In particular, a CMOS semiconductor device whose deign rule is 50 nm or below encounters intrinsic and crucial problems. For example, there are elicitation of variation in a threshold voltage (Vth) due to a fluctuation in dopant concentration in a channel region, an increase in an effective gate insulator thickness due to generation of a depletion layer in a gate electrode, and others.

As one of methods which solve such problems, there is a so-called full-silicide (FUSI) gate electrode technology of silicidation of a polysilicon gate electrode over entire thicknesses (see, e.g., a specification in U.S. Pat. No. 6,929,992). However, all MOSFETs in a single semiconductor device do not have to be formed into FUSI gate electrodes, and forming some MOSFETs, e.g., a pMOSFET, alone into the FUSI gate electrode is preferable. A technology of selectively forming some MOSFETs alone into the FUSI gate electrodes is disclosed in, e.g., Jpn. Pat. Appln. KOKAI Publication No. 2005-228868. In the technology disclosed in such a patent, a manufacturing process is complicated. For example, a polysilicon film of a gate electrode to be formed into the FUSI is selectively reduced in thickness, or silicidation of a source/drain and silicidation of a gate electrode are individually carried out.

### BRIEF SUMMARY OF THE INVENTION

According to one aspect of the present invention, there is provided a semiconductor device comprising: a first field effect transistor (MOSFET); and a second field effect transistor (MOSFET), the first field effect transistor including: a first gate electrode provided on a gate insulator on a semiconductor substrate and formed of a first metal silicide layer; a first insulator provided to be adjacent to a side surface of the first gate electrode; and a first sidewall including the first insulator, the second field effect transistor including: a second gate electrode provided on a gate insulator on the semiconductor substrate and formed of a conductor film including a polysilicon layer and a second metal silicide layer; a second insulator different from the first insulator provided to be adjacent to a side surface of the second gate electrode; and a second sidewall including the second insulator.

According to another aspect of the present invention, there is provided a manufacturing method of a semiconductor device, comprising: forming a first gate electrode and a second gate electrode, each of the first and second gate electrodes formed of polysilicon on a gate insulator on a semiconductor substrate; forming a silicon nitride film to be adjacent to a side surface of the first gate electrode; forming a silicon oxide film to be adjacent to a side surface of the second gate electrode; forming a first sidewall on the side surface of the first gate electrode, the first sidewall including the silicon nitride film and the silicon oxide film, and forming a second sidewall on a side surface of the second gate electrode, the second sidewall including the silicon oxide film; forming a first diffusion layer in the semiconductor substrate by using the first gate electrode and the first sidewall as masks; forming a second diffusion layer in the semiconductor substrate by using the second gate electrode and the second sidewall as masks; depositing a siliciding metal to contact with upper surfaces of the first and second gate electrodes; and simultaneously siliciding the first and second gate electrodes to provide a full-silicide structure to the first gate electrode and a partial silicide structure to the second gate electrode.

### BRIEF DESCRIPTION OF SEVERAL VIEWS OF THE DRAWINGS

FIGS. 1A and 1B are views showing a relationship between a distance between a pMOSFET and an nMOSFET provided to be adjacent to each other and a variation in a threshold voltage (Vth) for explaining an influence of mutual diffusion of dopants in each gate electrodes of the pMOSFET and the nMOSFET;

FIG. 2 shows an example of a cross-sectional structure of a semiconductor device for explaining an embodiment of the present invention;

FIGS. 3A to 3C are process cross-sectional views for explaining an example of a manufacturing process of the semiconductor device according to the embodiment of the present invention;

FIGS. 4A and 4B are views showing a relationship between a distance between a gate electrode and an Si₃N₄ film and a thickness of a silicide layer being formed in the gate electrode according to the embodiment of the present invention;

FIG. 5 is a view showing a relationship between a gate length and a threshold voltage (Vth) according to the embodiment of the present invention; and

FIG. 6 shows a cross-sectional structure of a semiconductor device for explaining an example of a modification of the present invention.

### DETAILED DESCRIPTION OF THE INVENTION

According to an embodiment of the present invention, a semiconductor device having a simple structure in which a full-silicide (FUSI) gate electrode is selectively formed and a manufacturing method thereof are provided. In particular, in a semiconductor device including a plurality of types of MOSFETs, there are provided a semiconductor device in which an FUSI gate electrode and a partial silicide gate electrode are selectively formed by forming sidewall of each gate electrodes different from each other, and a manufacturing method thereof.

In a CMOS semiconductor device, when both a pMOSFET and an nMOSFET are formed into FUSI gate electrodes, variation in threshold voltage (Vth) due to a fluctuation in dopant concentration in a channel region is similarly improved in a pMOSFET and an nMOSFET. However, in other characteristics, performance of the pMOSFET can be greatly improved, but performance of the nMOSFET may be degraded in some cases. Some of such examples will now be explained below.

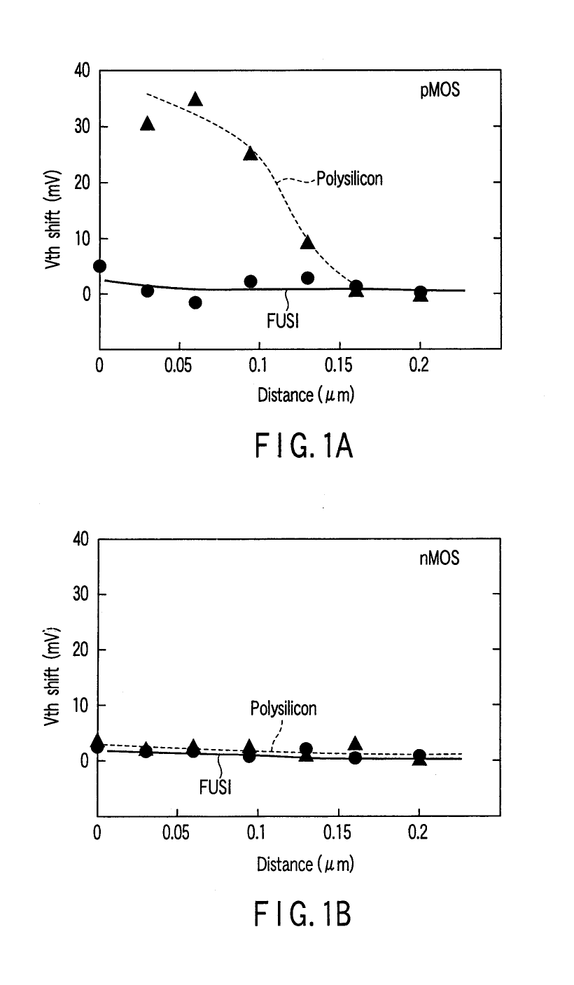

A consideration will be given as to an example where a pMOSFET and an nMOSFET are arranged to be adjacent to each other like a static random access memory (SRAM), a p-type impurity is doped in a gate electrode of the pMOSFET at a high concentration, and an n-type impurity is doped in a gate electrode of the nMOSFET at a high concentration. In case of an SRAM whose design rule is 50 nm or below, when the pMOSFET and the nMOSFET are provided in close proximity to each other, impurities which are opposite electroconductive type each other are mutually diffused in other gate electrodes during a manufacturing process. FIGS. 1A and 1B are views showing a relationship between a distance between the pMOSFET and the nMOSFET and a variation in threshold voltage (Vth) for explaining an influence of this mutual diffusion, and FIGS. 1A and 1B respectively depict characteristics of the pMOSFET and the nMOSFET. In case of the pMOSFET, in a polysilicon gate electrode, a variation in Vth is increased due to mutual diffusion when a distance between the semiconductor devices is reduced to 0.15 μm or below. However, in an FUSI gate electrode, such a change in Vth hardly occurs. On the other hand, in case of the nMOSFET, such a variation in Vth is hardly observed in both the polysilicon gate electrode and the FUSI gate electrode. Therefore, it can be said that a benefit of the FUSI electrode is large in the pMOSFET.

Further, in regard to an influence of a depletion layer formed in the gate electrode, when the polysilicon gate electrode is substituted by the FUSI gate electrode, an effective gate insulator film thickness reduction effect of approximately 0.4 nm of silicon oxide (SiO₂) film thickness equivalent can be obtained in the pMOSFET. However, although the nMOSFET has such an effect, it is smaller than that of the pMOSFET and the reduction effect is only approximately 0.1 nm of SiO₂ film thickness equivalent.

Furthermore, as to degradation in characteristics of the nMOSFET due to using the FUSI gate electrode, it is revealed that a leak current is substantially doubled at an edge of a gate electrode or realizing a low threshold voltage is difficult.

The embodiments of the present invention will be described with reference to the accompanying drawings. The accompanying drawings, which are incorporated in and constitute a part of the specification, illustrate embodiments of the invention, and together with the general description given above and the detailed description of the embodiments given below, serve to explain principles of the invention. Throughout the drawings, corresponding portions are denoted by corresponding reference numerals. The embodiments are only examples, and various changes and modifications can be made without departing from the scope and spirit of the present invention.

### Embodiment

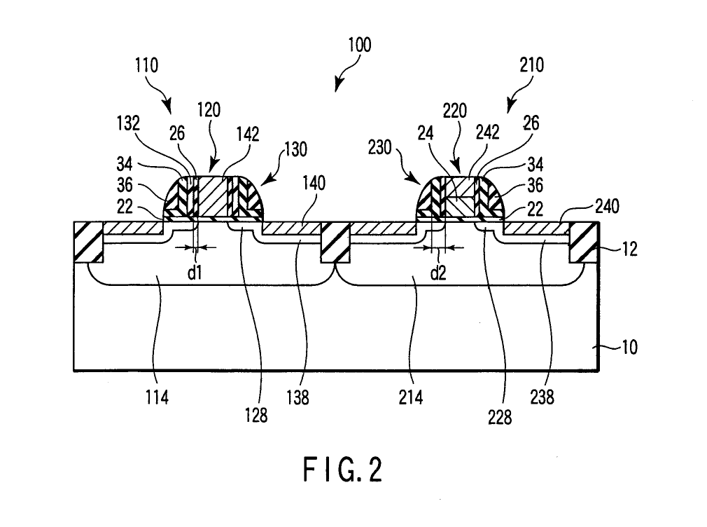

FIG. 2 shows an example of a cross-sectional structure of a semiconductor device according to an embodiment of the present invention. A semiconductor device 100 of this embodiment includes a first semiconductor element device 110, e.g., a pMOSFET, and a second semiconductor element device 210, e.g., an nMOSFET, formed on a semiconductor substrate 10, e.g., a silicon substrate.

A first gate electrode 120 of the first semiconductor element device (pMOSFET) 110 is a full-silicide (FUSI) gate electrode, entire thickness of which is formed of a second conductor film 142 made of silicide, e.g., nickel silicide (NiSi). The first gate electrode 120 includes a first gate sidewall 130 containing a first sidewall insulator 132 formed of a silicon nitride film (Si₃N₄ film) which is adjacently provided within a distance of 5 nm or below from a side surface of the first gate electrode 120.

A second gate electrode 220 of the second semiconductor element device (nMOSFET) 210 is a partial silicide gate electrode which includes a first conductor film 24, e.g., a polysilicon film, and a second conductor film 242 made of silicide, e.g., NiSi. The second gate electrode 220 includes a second gate sidewall 230 containing a second sidewall insulator 34 formed of a silicon oxide film (SiO₂ film) which is adjacently provided on a side surface of the second gate electrode 220 and has a thickness of 10 nm or above. Therefore, the second gate sidewall 230 has a structure different from that of the first gate sidewall 130.

Although the second conductor films 142 and 242 formed of silicide, e.g., NiSi, in the first and second gate electrodes 120 and 220 are simultaneously formed, they are controlled in such a manner that each thickness of silicide layers to be formed different each other by changing the sidewall structure as explained above. Further, the silicide layers (the second conductor films) 142 and 242 of these gate electrodes can be formed simultaneously with silicide layers (the second conductor layers) 140 and 240 formed on sources/drains 138 and 238. That is, all required silicide layers can be formed in a single silicidation step. As will be explained later in detail, this embodiment is particularly effective for a fine semiconductor device with a gate length of 50 nm or below.

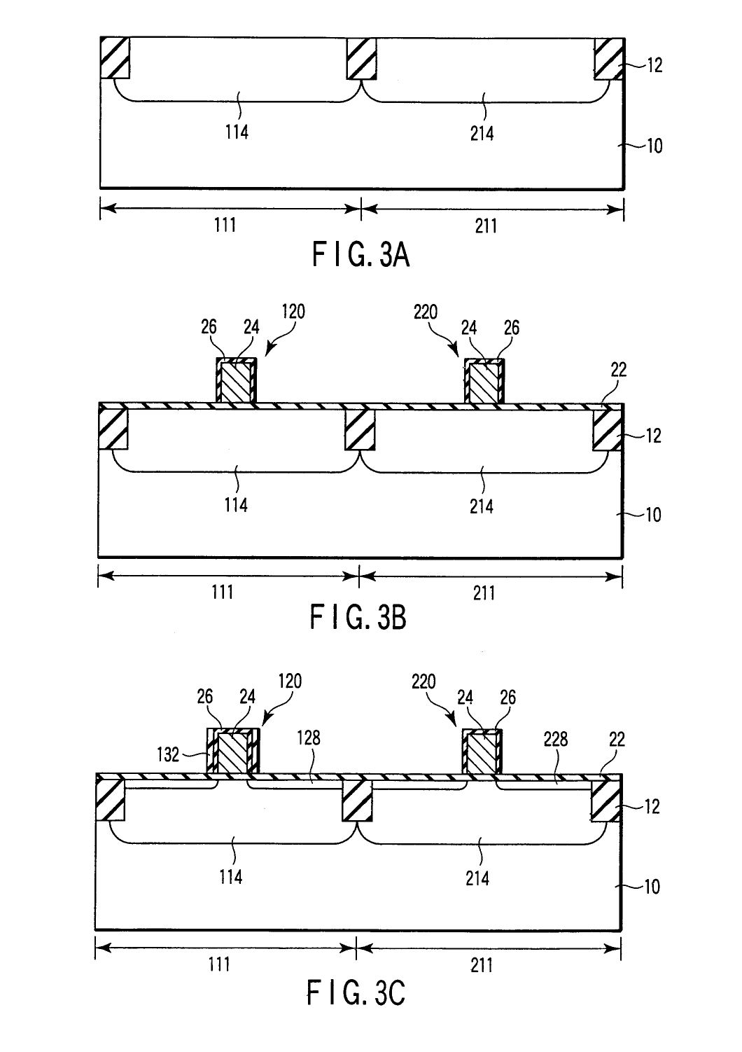

An example of a manufacturing process of the semiconductor device 100 according to this embodiment will now be explained with reference to process cross-sectional views of FIGS. 3A to 3C.

Referring to FIG. 3A, isolations 12 and wells 114 and 214 are formed in the semiconductor substrate 10, e.g., a silicon substrate. As the isolation 12, it is possible to use a shallow trench isolation (STI) which can be obtained by forming a shallow trench in the semiconductor substrate 10 in an isolation region and filling the isolation trench with an isolation insulator, e.g., an SiO₂ film. However, the isolation 12 can be formed by using any other method, e.g., local oxidation of silicon (LOCOS).

An n-type impurity, e.g., phosphor (P), is deeply doped in a first semiconductor region 111 where the first semiconductor element device 110, e.g., pMOSFET, is formed, thereby forming the first well 114, e.g., n well. Likewise, a p-type impurity, e.g., boron (B), is deeply doped in a second semiconductor region 211 where the second semiconductor element device 210, e.g., nMOSFET, is formed, thereby forming the second well 214, e.g., p well.

Referring to FIG. 3B, a gate insulator 22 is formed on an entire surface of the semiconductor substrate 10. As the gate insulator 22, it is possible to use an SiO₂ film formed by thermal oxidation or chemical vapor deposition (CVD), a silicon oxynitride film (SiON film), or a high-dielectric-constant insulator having a dielectric constant higher than these films, e.g., a tantalum oxide film (Ta₂O₅ film). Although a thickness of the gate insulator 22 varies depending on a design of the semiconductor device, it can be set to, e.g., 1.0 to 1.8 nm of SiO₂ film thickness equivalent.

A first conductor film 24 is formed on an entire surface of the gate insulator 22. As the first conductor film 24, a polysilicon film formed by CVD can be used, for example. It is preferable to set a film thickness of the first conductor film 24 to 60 to 100 nm for full silicidation which will be explained later in detail. An n-type impurity, e.g., phosphor (P) or arsenic (As), is doped in the first conductor film 24 in the second semiconductor region 211 where the second semiconductor element device 210 is formed. Then, a p-type impurity, e.g., boron (B), can be doped, if required, in the first conductor film 24 in the first semiconductor region 111 where the first semiconductor element device 110 is formed.

Subsequently, patterns of the first and second gate electrodes 120 and 220 are formed in a resist film (not shown) provided on the first conductor film 24, and the patterned resist film is used as a mask to etch the first conductor film 24 by, e.g., reactive ion etching (RIE). In this manner, the first and second gate electrodes 120 and 220 are patterned. As to patterning of the gate electrodes, a hard mask process can be used in which patterns of the gate electrodes is transferred onto a hard mask film, such as an SiO₂ film or an Si₃N₄ film, in place of the resist film, and the hard mask film is used as a mask to perform etching.

Gate post-oxidation can be carried out to improve degradation in reliability of the gate insulator 22 due to processing damage in the gate electrodes. Gate post-oxidation is performed at, e.g., 650 to 750° C., and a post-oxide film 26 having a thickness of approximately 0.5 to 2.0 nm is formed on the surface of each of the first and second gate electrodes 120 and 220. When gate post-oxidation is carried out at the above-mentioned temperature, the impurities doped in the gate electrodes can be prevented from being deactivated. The gate post-oxide film 26 can be removed thereafter as required. Further, gate post-oxidation can be omitted.

Referring to FIG. 3C, the first and second gate electrodes 120 and 220 are used as masks to effect ion implantation, thereby forming shallow diffusion layers as first and second extensions 128 and 228 having a low impurity concentration. For example, boron (B) is doped in the silicon substrate 10 in the first semiconductor region 111 where the first semiconductor element device 110 is formed, and arsenic (As) is doped in the silicon substrate 10 in the second semiconductor region 211 where the second semiconductor element device 210 is formed. When forming the extensions, an offset spacer can be formed to improve short-channel characteristics of the MOSFETs and improve sheet resistances of the extensions.

Then, the first sidewall insulator 132 is formed on the entire surface to cover the first and second gate electrodes 120 and 220. The first sidewall insulator 132 is an Si₃N₄ film formed by, e.g., low-pressure CVD (LPCVD). Subsequently, the first sidewall insulator 132 is subjected to anisotropic etching by, e.g., RIE, so that the first sidewall insulator 132 is left only on side surfaces of the first and second gate electrodes 120 and 220. Then, the first semiconductor region 111 is covered with a resist film (not shown), and the first sidewall insulator 132 left on the side surface of the second gate electrode 220 is removed. In this manner, the structure depicted in FIG. 3C is formed.

Then, referring to FIG. 2, the second sidewall insulator 34 is formed on the entire surface, and a third sidewall insulator 36 is deposited thereon. The second sidewall insulator 34 is an SiO₂ film having a thickness of 10 nm or above, and it is, for example, an SiO₂ film which is deposited by CVD and has a thickness of 10 to 20 nm. As the third sidewall insulator 36, an Si₃N₄ film which is, for example, deposited by CVD at 400 to 600° C. and has a thickness of 10 to 80 nm can be used.

The silicon substrate 10 is used as a stopper for etching to subject the third and second sidewall insulators 36 and 34 to anisotropic etching by, e.g., RIE, thereby forming the first and second gate sidewalls 130 and 230 on the side surfaces of the first and second gate electrodes 120 and 220. The first gate sidewall 130 of the first semiconductor element device 110 is a three-layer sidewall including the first, second, and third sidewall insulators 132, 34, and 36, and the second gate sidewall 230 of the second semiconductor element device 210 is a two-layer sidewall including the second and third sidewall insulators 34 and 36. In this manner, as shown in FIG. 2, the first and second gate sidewalls 130 and 230 having different structures can be formed in the first semiconductor element device 110 and the second semiconductor element device 210.

Then, the second semiconductor region 211 is covered with a resist film (not shown), and the first gate electrode 120 and the first gate sidewall 130 are used as masks to ion-implant a high-concentration p-type impurity, e.g., boron (B), into the silicon substrate 10 in the first semiconductor region 111 in such a manner that the impurity is implanted to be deeper than the first extension 128. Likewise, the second gate electrode 220 and the second gate sidewall 230 are used as masks to ion-implant an n-type impurity, e.g., arsenic (As), with a high-concentration into the silicon substrate 10 in the second semiconductor region 211 in such a manner that the impurity is implanted to be deeper than the second extension 228. In order to electrically activate the implanted impurities, annealing is carried out for a short period of time at a temperature of, e.g., approximately 950 to 1100° C., by RTA (rapid thermal annealing) or spike annealing, thereby forming source/drain diffusion layers. In this manner, a first source/drain 138 of the first semiconductor element device 110 and a second source/drain 238 of the second semiconductor element device 210 can be formed.

Subsequently, the oxide films 26 on the upper surfaces of the first and second gate electrodes 120 and 220 and the oxide films 22 on the surfaces of the first and second sources/drains 138 and 238 are removed by, e.g., wet etching, thereby exposing silicon surfaces. Moreover, a siliciding metal (not shown), e.g., nickel (Ni), is deposited on the entire surface by sputtering. A film thickness of the siliciding metal is thick enough to completely silicide the second gate electrode 220 but thin enough not to increase a leak current of the source/drain 138 and 238 when the silicide layers are simultaneously formed, and is preferably 6 to 12 nm.

Then, first silicidation annealing is carried out. The first silicidation annealing is an annealing for a short period of time at a low temperature with which silicidation is not completely performed. It is, e.g., RTA (rapid thermal annealing) at approximately 350° C. As a result of the first annealing, the silicon 24 on the upper surfaces of the gate electrodes 120 and 220 and the surface of the first and second sources/drains 138 and 238 which are in contact with the siliciding metal film reacts to form an intermediate silicide. When using Ni as the siliciding metal, the intermediate silicide has a composition of, e.g., NiₓSi (1<x<2). After the first silicidation annealing, the unreacted siliciding metal is removed.

Then, second silicidation annealing is carried out at a higher temperature than that of the first annealing, e.g., approximately 500° C. by RTA. Second annealing is performed in such a manner that an intermediate silicide sufficiently reacts with the silicon to form a complete silicide (e.g., a nickel mono-silicide (NiSi)).

In the second annealing, as shown in FIG. 2, the entire film thickness of the first conductor film (a polysilicon film) 24 of the first gate electrode 120 is changed into a silicide layer 142 by an effect caused by the first sidewall 130. That is, the gate electrode 120 having the FUSI structure is formed. On the other hand, in the second gate electrode 220, a silicide layer 242 is formed near a surface layer of the polysilicon layer 24 alone, and the partial silicide gate electrode 220 having the two-layer structure including the silicide layer 242 and the polysilicon layer 24 is formed. Furthermore, silicide layers 140 and 240 are also formed on the surface layers of the first and second sources/drains 138 and 238. A thickness of the silicide layers 140 and 240 is less than a thickness of the silicide layer 142 of the first gate electrode 120. When a thickness of the siliciding metal is set to the above-explained range, leak currents of the first and second sources/drains 138 and 238 caused by forming the silicide layers 140 and 240 can be prevented from being increased, since the silicide layers 140 and 240 are formed to be thin.

It is to be noted that, for example, a nickel platinum silicide (NiPtSi) can be used as the silicide besides the nickel silicide. In this case, according to this embodiment, the FUSI gate electrode and the partial silicide gate electrode can be individually formed at the same time.

In this manner, the structure of the gate electrode in the semiconductor device 100 according to this embodiment depicted in FIG. 2 can be formed. Then, the semiconductor device according to this embodiment is brought to completion through processes required for the semiconductor device, e.g., multilevel wiring.

As explained above, it is possible to manufacture the semiconductor device according to this embodiment in which the first semiconductor element device, e.g., a pMOSFET, has the gate electrode of FUSI structure formed of the silicide layer alone and the second semiconductor element device, e.g., an nMOSFET, has the gate electrode of the partial silicide structure including the polysilicon layer and the silicide layer.

According to this embodiment, the pMOSFET gate electrode having the FUSI structure, the nMOSFET gate electrode having the partial silicide structure, and the silicide layer of the source/drain can be all formed at a single silicidation step without performing special processing. That is, in a conventional technology, a thickness of the polysilicon film of the gate electrode alone where the FUSI structure is formed is reduced to form the FUSI structure and the partial silicide structure, separately. However, in this embodiment, such a process is not required. Further, in the conventional technology, silicidation of the gate electrode and formation of the silicide layer on the source/drain are performed separately in different two silicidation steps. However, in this embodiment, they can be formed in-the single silicidation step. Therefore, the silicidation step can be simplified as compared with the conventional technology.

The characteristics of the gate sidewall according to the embodiment of the present invention will now be explained in detail. As explained above, in the first gate sidewall 130 of the pMOSFET (the first semiconductor element device 110), the first sidewall insulator 132 formed of the Si₃N₄ film is provided to be adjacent to the gate electrode 120. However, in the second gate sidewall 230 of the nMOSFET (the second semiconductor element device 210), this first sidewall insulator is not included, and the second sidewall insulator formed of the SiO₂ film is provided to be adjacent to the gate electrode 230. In this manner, this embodiment is unique in fully siliciding the polysilicon film 24 of the gate electrode 130 by providing the Si₃N₄ film to be adjacent to the gate electrode.

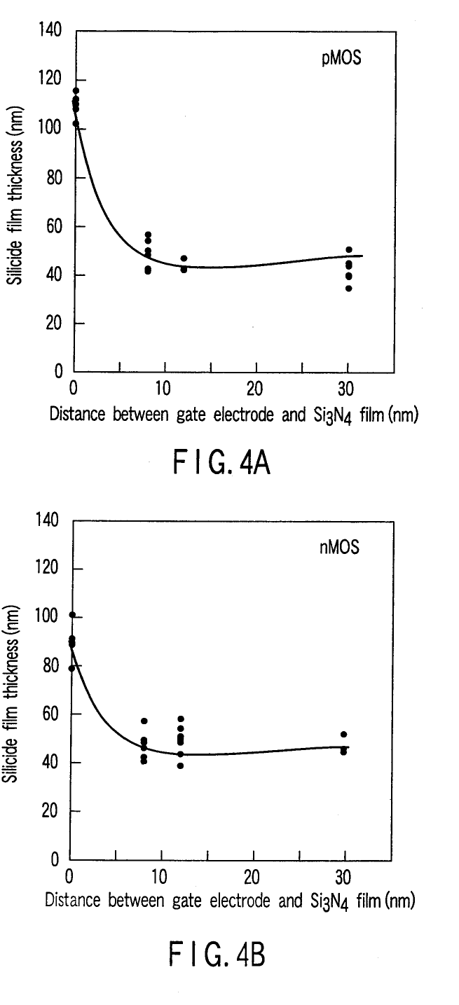

A thickness of the polysilicon gate electrode to be silicided varies depending on a distance between the side surface of the gate electrode and the Si₃N₄ film (see d1 and d2 in FIG. 2). FIGS. 4A and 4B are views showing a relationship between a distance between the gate electrode and the Si₃N₄ film and a thickness of the silicide layer to be formed in the gate electrode. The distance between the gate electrode and the Si₃N₄ film is a film thickness of the SiO₂ film sandwiched between these members. FIGS. 4A and 4B show examples of the pMOSFET and the nMOSFET, respectively. In both cases, when the Si₃N₄ film is provided in direct contact with the gate electrode, the thickness of the silicide layer to be formed in the gate electrode has the largest value. The maximum thickness of the silicide layer formed under such silicidation conditions used in the figure is approximately 110 nm in case of the pMOSFET, whereas it is approximately 90 nm in case of the nMOSFET. That is, the gate electrode of the pMOSFET has the larger thickness of the silicide layer to be formed than the gate electrode of the nMOSFET. Furthermore, when the thickness of the SiO₂ film sandwiched between the gate electrode and the Si₃N₄ film is increased, the thickness of the silicide layer to be formed is reduced. When the thickness of the SiO₂ film becomes 10 nm or above, the thickness of the silicide layer is almost constant around 45 nm. Controlling the structure of the gate sidewall in this manner enables controlling the thickness of the silicide layers to be formed in the gate electrodes to different thicknesses. Therefore, in order to form a silicide layer having a thickness of 60 nm or above in the gate electrode of the pMOSFET, setting the distance (d1) between the gate electrode and the Si₃N₄ film to 5 nm or below is preferable. On the other hand, in the nMOSFET in which the FUSI gate electrode is not required, setting a thickness of the SiO₂ film contacting with the gate electrode to 10 nm or above is preferable to make the distance (d2) between the gate electrode and the Si₃N₄ film to 10 nm or above.

In general, a film thickness of the polysilicon film used for the gate electrode is approximately 100 nm in a semiconductor device whose design rule is 50 nm or below. According to this embodiment, the silicide layer of the pMOSFET can be formed within the range of 60 mm to 100 nm. When the SiO₂ film having a thickness of 10 nm or above is formed on the sidewall of the nMOSFET, the formed silicide layer thickness is approximately 45 nm in average as explained above with reference to FIGS. 4A and 4B, and its variation can be estimated as ±10 nm. Therefore, when the thickness of the polysilicon film of the gate electrode is set to 60 to 100 nm, the FUSI gate electrode can be realized in the pMOSFET. At the same time, polysilicon is not completely silicided in the nMOSFET, and thus the partial silicide gate electrode can be realized.

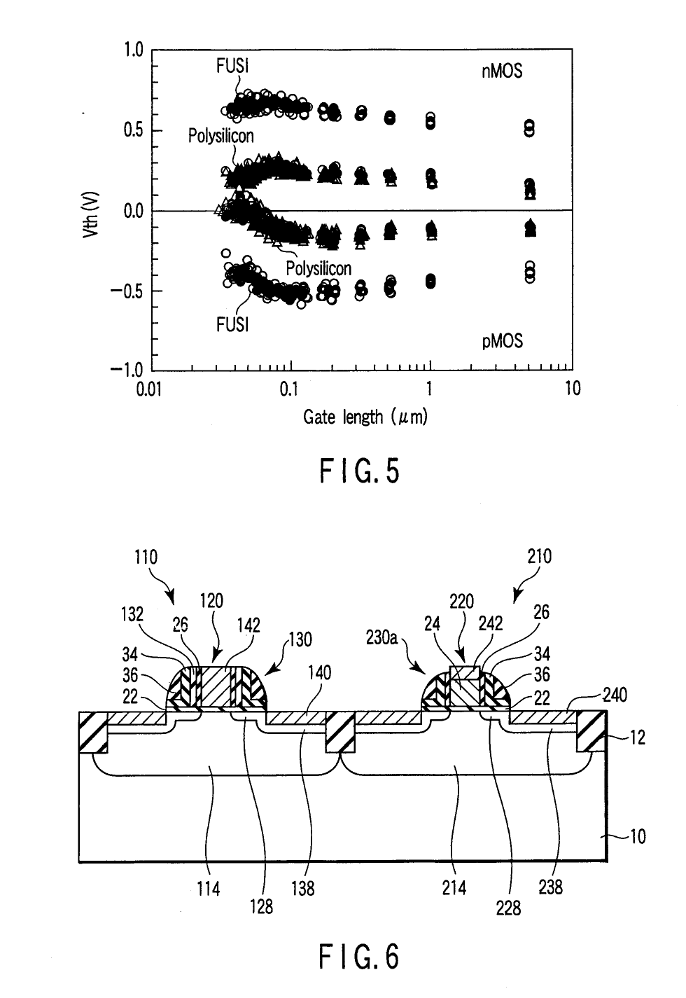

A suitable gate length to which this embodiment can be applied will now be explained with reference to FIG. 5. A gate length is, e.g., a width of the gate electrode 120 or 220 of the semiconductor element device depicted in FIG. 2, more specifically, a bottom width of the gate electrode contacting with a gate insulator in a channel direction. FIG. 5 is a view showing a relationship between a gate length and a threshold voltage (Vth). When the gate electrode has the FUSI structure, an absolute value of Vth is sharply increased as compared with the polysilicon gate electrode. As shown in FIG. 5, in both the pMOSFET and the nMOSFET, Vth is increased with all gate lengths in the FUSI gate electrode, and the drawing also shows that the FUSI structure can be formed when the gate length falls within a range of 0.03 and 5 μm. Although not depicted, it has been confirmed that the gate electrode having the FUSI structure can be formed when the gate length is 20 μm at a maximum.

In a semiconductor device whose design rule is 50 nm or below, it is desired to control an absolute value of Vth to fall within a range of 0.25V to 0.4V in terms of the device designing. As depicted in FIG. 5, in the pMOSFET in which the gate length is 50 nm or below, the FUSI structure can satisfy the requirement of Vth. However, when the gate length exceeds 50 nm, Vth is increased to approximately −0.5V. On the other hand, in the nMOSFET, the gate electrode having the FUSI structure has large Vth in all gate lengths, and hence the Vth requirement cannot be satisfied.

Further, when providing the FUSI structure to the gate electrode whose gate length exceeds 50 nm, it becomes difficult to realize both silicidation of the gate electrode and that of the source/drain at the single silicidation step like in the embodiment. That is, a thickness of the silicide layer on the source/drain becomes too large, and thus a problem of an increased leak current occurs.

Therefore, it is preferable to apply this embodiment to a semiconductor device in which the gate length is 50 nm or below.

### Modification

This embodiment can be modified and carried out in various ways. FIG. 6 shows such an example. A semiconductor device depicted in FIG. 6 is formed in such a manner that a height of a second gate sidewall 230a in a second semiconductor element device 210, e.g., nMOSFET, is lower than a height of a second gate electrode 220. It is to be noted that a height of a first gate sidewall 130 is substantially equal to a height of a first gate electrode in a first semiconductor element device 110, e.g., pMOSFET. When such a second gate sidewall 230a structure is provided, the second gate electrode 220 can be suppressed in the silicidation. In such a structure, a part of the gate electrode which is substantially above the height of the gate sidewall is silicided, and rest of the part of the same which is below the height of the gate sidewall is suppressed from being silicided.

According to the sidewall structure of this modification, a difference in thickness between the silicide layer 142 in the first gate electrode 120 and the silicide layer 242 of the second gate electrode 220 can be increased, thus assuring a larger process margin.

Like the foregoing embodiment, a semiconductor device including a first semiconductor element device, e.g., pMOSFET, having a FUSI structure gate electrode formed of the silicide and a second semiconductor element device, e.g., nMOSFET, having a partial silicide structure gate electrode including polysilicon and silicide layers has the following advantages.

In the pMOSFET, a resistance of the gate electrode can be reduced by the FUSI structure. As a result, formation of a depletion layer in the gate electrode can be greatly suppressed. Furthermore, it is possible to suppress variation in threshold voltage due to mutual diffusion of dopants from the gate electrode of nMOSFET provided adjacently like in SRAM, for example. Moreover, variation in threshold voltage due to a fluctuation in a carrier concentration in a channel region can be suppressed.

On the other hand, in an nMOSFET, since the gate electrode has the partial silicide structure, an increase in gate leak can be suppressed, thus realizing a low threshold voltage.

Additionally, according to the embodiment of the present invention, the silicide layer of the FUSI gate electrode, the silicide layer of the partial silicide gate electrode, and the silicide layer of the source/drain can be simultaneously formed in a single silicidation step, and thus the number of manufacturing steps is not increased. Further, when a film thickness of a metal used for silicidation is set to fall within the appropriate range, a junction leak between the source/drain and the substrate can be suppressed, thereby forming the semiconductor device superior in junction leak characteristics.

As explained above, appropriately setting a temperature at each thermal treatment step enables suppressing an impurity doped in the gate electrode from being deactivated. As a result, formation of depletion layer in the gate electrode of the nMOSFET can be suppressed in particular.

Therefore, by virtue of these effects, the CMOS semiconductor device in which both the pMOSFET and the nMOSFET have high performance can be provided. When the device structure according to the embodiment of the present invention is applied to cells of SRAM whose design rule is 50 nm or below in particular, the SRAM cell in which variation in characteristics is suppressed can be realized.

As explained above, according to the embodiment of the present invention, differentiating the gate sidewall structure of the pMOSFET and that of the nMOSFET enables to form the gate electrodes having fine dimensions into different structures, the FUSI structure and the partial silicide structure. As a result, transistor performance of the pMOSFET can be greatly improved without degrading transistor performance of the nMOSFET and the manufacturing process can be simplified.

Although the present invention has been explained in the foregoing embodiment while taking the CMOS semiconductor device as an example, the present invention is not limited to the CMOS semiconductor device and can be applied to wide variety of semiconductor devices. For example, the present invention can be applied to a semiconductor device including both a semiconductor element device which operates at a high speed and a semiconductor element device which operates at a low speed. That is, when the gate electrode sidewall of the high-speed semiconductor element device employs that of the pMOSFET of the present invention, the gate electrode of the high-speed semiconductor element device alone can be selectively formed into the FUSI gate electrode. This enables to avoid formation of depletion layer in the gate electrode of the high-speed semiconductor element device and contribute to an increased operation speed.

As explained above, according to the embodiment of the present invention, the semiconductor device having the simple structure in which the FUSI gate electrode is selectively formed and the manufacturing method thereof are provided.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first field effect transistor (MOSFET); and
a second field effect transistor (MOSFET),
the first field effect transistor including:
a first gate electrode provided on a gate insulator on a semiconductor substrate and formed of a first metal silicide layer;
a first insulator provided to be adjacent to a side surface of the first gate electrode; and
a first sidewall including the first insulator,
the second field effect transistor including:
a second gate electrode provided on a gate insulator on the semiconductor substrate and formed of a conductor film including a polysilicon layer and a second metal silicide layer;
a second insulator different from the first insulator provided to be adjacent to a side surface of the second gate electrode; and
a second sidewall including the second insulator.

2. The device according to claim 1, wherein
the first insulator is a silicon nitride film, and a distance between the first gate electrode and the first insulator is 5 nm or below, and
the second insulator is a silicon oxide film having a thickness of at least 10 nm.

3. The device according to claim 2, wherein
the first field effect transistor is a p-channel field effect transistor, and
the second field effect transistor is an n-channel field effect transistor.

4. The device according to claim 3, wherein a gate length of each of the first and second field effect transistors is 50 nm or below.

5. The device according to claim 3, wherein a thickness of each of the first and second gate electrodes is 60 nm or above and 100 nm or below.

6. The device according to claim 3, wherein a thickness of the second metal silicide layer is smaller than a thickness of the first metal silicide layer.

7. The device according to claim 6, wherein the thickness of the first metal silicide layer is 60 nm or above, and the thickness of the second metal silicide layer is 55 nm or below.

8. The device according to claim 3, comprising:
a pair of first diffusion layers provided in the semiconductor substrate to dispose the first gate electrode therebetween;
a third metal silicide layer provided in each first diffusion layer;
a pair of second diffusion layers provided in the semiconductor substrate to dispose the second gate electrode therebetween; and
a fourth metal silicide layer provided in each second diffusion layer, and
each of the first, second, third, and fourth metal silicide layers is formed of a nickel silicide or a nickel platinum silicide.

9. The device according to claim 3, wherein a height of the first sidewall is equal to a height of the first gate electrode, and a height of the second sidewall is lower than a height of the second gate electrode.

10. The device according to claim 1, wherein a gate length of each of the first and second field effect transistors is 50 nm or below.

11. The device according to claim 1, wherein a thickness of the second metal silicide layer is smaller than a thickness of the first metal silicide layer.

12. The device according to claim 1, wherein each of the first and second metal silicide layers is formed of a nickel silicide or a nickel platinum silicide.

13. The device according to claim 1, wherein a height of the first sidewall is equal to a height of the first gate electrode, and a height of the second sidewall is lower than a height of the second gate electrode.

14. A manufacturing method of a semiconductor device, comprising:
forming a first gate electrode and a second gate electrode, each of the first and second gate electrodes formed of polysilicon on a gate insulator on a semiconductor substrate;
forming a silicon nitride film to be adjacent to a side surface of the first gate electrode;
forming a silicon oxide film to be adjacent to a side surface of the second gate electrode;
forming a first sidewall on the side surface of the first gate electrode, the first sidewall including the silicon nitride film and the silicon oxide film, and forming a second sidewall on a side surface of the second gate electrode, the second sidewall including the silicon oxide film;
forming a first diffusion layer in the semiconductor substrate by using the first gate electrode and the first sidewall as masks;
forming a second diffusion layer in the semiconductor substrate by using the second gate electrode and the second sidewall as masks;
depositing a siliciding metal to contact with upper surfaces of the first and second gate electrodes; and
simultaneously siliciding the first and second gate electrodes to provide a full-silicide structure to the first gate electrode and a partial silicide structure to the second gate electrode.

15. The method according to claim 14, wherein each of the first and second gate electrodes is formed with a gate length of 50 nm or below.

16. The method according to claim 14, wherein
the first diffusion layer is a p-type diffusion layer, and a distance between the silicon nitride film and the first gate electrode is 5 nm or below, and
the second diffusion layer is an n-type diffusion layer, and a distance between the silicon oxide film and the second gate electrode is 10 nm or above.

17. The method according to claim 14, wherein
the siliciding metal is further deposited to contact with upper surfaces of the first and second diffusion layers, and
wherein the siliciding further includes forming a silicide layer in each of the first and second diffusion layers.

18. The method according to claim 17, wherein a thickness of the siliciding metal is in the range of 6 to 12 nm.

19. The method according to claim 14, wherein the silicide layer of the first gate electrode is formed with a thickness of 60 nm or above, and the silicide layer of the second gate electrode is formed with a thickness of 55 nm or below.

20. The method according to claim 14, wherein the first sidewall is formed with a height equal to that of the first gate electrode, and the second sidewall is formed with a height lower than that of the second gate electrode.
